(19) United States
(12) Patent Application Publication
(10) Pub. No.: US 2017/0190610 A1
(43) Pub. Date: Jul. 6, 2017

(54) FUNCTIONALIZED SUBSTRATE

(71) Applicant: SAINT-GOBAIN PERFORMANCE PLASTICS CORPORATION, Solon, OH (US)

(72) Inventors: Camille JOSEPH, Nantes (FR); Laura J. SINGH, Paris (FR); Yemima Anne BON SAINT COME, Paris (FR); Charles LEYDER, Cambridge, MA (US)

(21) Appl. No.: 15/393,570

(22) Filed: Dec. 29, 2016

Related U.S. Application Data
(60) Provisional application No. 62/273,725, filed on Dec. 31, 2015.

(51) Int. Cl. C03C 17/00; C03C 17/36; G02B 5/20; C23C 14/20; C23C 14/10; C23C 14/00; C03C 17/34; C23C 14/35

(52) U.S. Cl. CPC C03C 17/007; C03C 17/008; C03C 17/3417; C03C 17/36; C23C 14/35; C23C 14/205; C23C 14/10; C23C 14/0036; G02B 5/208; C03C 2217/48; C03C 2217/45; C03C 2217/475; C03C 2217/948; C03C 2218/156; C03C 2218/322

(57) ABSTRACT

The present invention relates to a functionalized substrate comprising a substrate (10) and a near infrared absorbing coating (20), wherein said near infrared absorbing coating (20) comprises near infrared absorbing nanoparticles (21) comprising indium, tin, zinc, antimony, aluminum, tungsten or mixtures thereof. In an embodiment, the near infrared absorbing coating (20) further includes an inorganic matrix (22, 23, 24).

### CROSS REFERENCE TO RELATED APPLICATION

This Application claims priority under 35 U.S.C. §119(e) to U.S. Provisional Application No. 62/273,725, entitled “FUNCTIONALIZED SUBSTRATE,” by Camille Joseph et al., filed on Dec. 31, 2015, which is assigned to the current assignee hereof and is incorporated herein by reference in its entirety.

### FIELD OF THE INVENTION

Embodiments of the present invention relate to a functionalized substrate comprising a near infrared absorbing coating and use thereof for solar control applications.

### BACKGROUND

Solar control coatings are widely used in the automotive and building industries for improving insulation of glazings as well as offering new possibilities of aesthetic modifications. Solar control function is based on near infrared (NIR) absorption or reflection.

NIR reflective coatings are generally made of stacks comprising metal layers, such as silver, as described for example in US 2006/0057399. However, those stacks may affect visible light transmission. In addition, metal layers, such as silver layers, may exhibit high conductivity that can block electromagnetic waves, which would be a drawback for mobile phone communications. Also, silver layers in particular have low stability and poor moisture and weather resistance, which may affect their optical properties and their efficiency as NIR reflecting layers.

NIR absorbing coatings can be provided using various functional layers. For example, U.S. Pat. No. 6,707,610 and WO 2008/036358 disclose window films comprising a TiN layer obtained by magnetron sputtering. However, those window films have rather low visible light transmission and are not selective. WO 2008/036363 suggests combining a TiN layer with a silver-based reflecting coating for improving the selectivity. However, such a combination still has the negative effect of silver layers.

Nanoparticles of various inorganic oxides, such as indium tin oxide (ITO) and antimony tin oxide (ATO), can absorb NIR radiations. For example, US 2010/0062242 discloses a window film comprising an IR reflecting layer comprising a metal layer, and an IR absorbing layer comprising IR absorbing nanoparticles dispersed in a cured polymeric binder. Such windows films present rather high visible light transmission and selectivity. NIR absorbing nanoparticles-containing coatings are generally obtained by wet-coating methods, as disclosed in US 2010/0062242. Wet-coating methods consist typically of depositing a thin layer of a solution comprising the nanoparticles and an organic binder on a substrate, and drying and/or curing the layer. For producing stacks of multilayers, the use of a two step wet-coating method may not be desired, in particular for stacks including layers deposited by magnetron sputtering. Industries continue to demand improved NIR absorbing nanoparticles-containing coatings that could be obtained by methods more compatible with the magnetron sputtering process.

### BRIEF DESCRIPTION OF THE DRAWINGS

Embodiments are illustrated by way of example and are not limited in the accompanying figures.

FIG. 1 includes a side elevation view of a functionalized substrate in accordance with an embodiment.

FIG. 2 includes a side elevation view of a functionalized substrate in accordance with another embodiment.

FIG. 3 includes a side elevation view of a functionalized substrate in accordance with a further embodiment.

FIG. 4 includes a side elevation view of a functionalized substrate in accordance with yet another embodiment.

FIG. 5 includes a side elevation view of a functionalized substrate in accordance with yet a further embodiment.

FIG. 6 includes a side elevation view of a near infrared absorbing nanoparticle layer disposed on a substrate in accordance with an embodiment.

FIG. 7 includes a side elevation view of a near infrared absorbing nanoparticle layer disposed on a substrate in accordance with another embodiment.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings.

The use of “a” or “an” is employed to describe elements and components described herein. This is done merely for convenience and to give a general sense of the scope of the invention. This description should be read to include one or at least one and the singular also includes the plural, or vice versa, unless it is clear that it is meant otherwise.

In a first aspect, the present invention relates to a functionalized substrate comprising a substrate and a near infrared (NIR) absorbing coating on said substrate. In a particular embodiment, said NIR absorbing coating is made of an inorganic matrix containing NIR absorbing nanoparticles comprising indium, tin, zinc, antimony, aluminum, tungsten or mixtures thereof.

In the context of the present application, NIR radiation refers to radiation from 780 to 2500 nm. By the expression “NIR absorbing” when referring to a coating or nanoparticles, it is meant that said coating or nanoparticles may absorb at least 10%, at least 15% or even at least 20% of the NIR radiation and may absorb up to 60%, up to 55% or up to 50% of the NIR radiation.

By the terms “on” and “under” when related to the relative position of one element (layer, structure or stack) to another, it is meant that said element is more distant from or closer to, respectively, the substrate than the other one. It is not meant that said elements are directly contacting each other, without excluding this possibility. In particular, additional elements may be present between said elements. On the contrary, the expression “direct contact” “directly on” or “directly under” when related to the relative position of one element to another means that no additional element is disposed between said elements.

The NIR absorbing nanoparticles comprise indium, tin, zinc, antimony, aluminum, tungsten or mixtures thereof. More particularly, the NIR absorbing nanoparticles may be based on partially or fully oxidized metals selected from indium, tin, zinc, antimony, aluminum, tungsten and alloys thereof. In the context of the present application, the expression “based on” when referring to the composition of an element (matrix, layer or nanoparticles) means that said element comprises more than 80%, more than 90%, or even more than 95% by weight of said material. Said element may be essentially made of said material.

In one embodiment, the NIR absorbing nanoparticles may be based on transparent conductive oxide (TCO). In particular, the NIR absorbing nanoparticles may be TCO nanoparticles. The TCO may be selected from indium tin oxide (ITO), indium zinc oxide (IZO), antimony tin oxide (ATO), tin zinc oxide (TZO), fluorine-doped tin oxide (FTO), aluminum-doped zinc oxide (AZO), gallium-doped zinc oxide (GZO), and optionally doped tungsten oxide.

In the context of the present application, ITO refers to mixed oxide of tin and indium wherein the tin content is generally from 1.5 to 16 wt %, such as from 4 to 10 wt %. IZO refers to mixed oxide of zinc and indium wherein the zinc content is generally from 10 to 60 wt %, such as from 15 to 40 wt %. ATO refers to mixed oxide of tin and antimony wherein the antimony content is generally from 2 to 15 wt %, such as from 2 to 8 wt %. TZO refers to mixed oxide of tin and zinc wherein the tin content is generally from 8 to 70 wt %, such as from 24 to 55 wt %. When referring to FTO, it is meant tin oxide comprising generally from 1 to 3 wt % of fluorine. AZO refers to zinc oxide comprising generally from 0.2 to 3 wt %, such as from 0.5 to 2 wt %, of aluminum oxide. GZO refers to zinc oxide comprising generally from 0.2 to 10 wt %, such as from 2 to 5 wt %, of gallium oxide. Optionally doped tungsten oxide refers to tungsten oxide which may comprise a dopant such as cesium. Cesium-doped tungsten oxide refers to CsₓW_{y}O_{z} wherein 0.001≦x/y≦1 and 2.2≦z/y≦3.0.

In another embodiment, the NIR absorbing nanoparticles may be partially oxidized metallic nanoparticles. By “partially oxidized” it is meant that not all of the metal atoms have been converted to their oxide form. The metallic nanoparticles may be based on indium, tin, zinc, antimony, aluminum, tungsten or alloys thereof. The partially oxidized nanoparticles may be in a uniform oxidized form, i.e. the degree of oxidation is substantially constant within the nanoparticles. Alternatively, the partially oxidized nanoparticles may have a core-shell structure with a metallic core and an at least partially oxidized shell or even a fully oxidized shell, such as a TCO shell.

In one embodiment, the NIR absorbing nanoparticles are spaced apart from each other. In particular, the NIR absorbing nanoparticles may form an array of discrete nanoparticles. The terms “spaced apart” or “discrete” are defined as meaning unconnected so that each nanoparticle does not touch a neighboring nanoparticle. In particular embodiments, the NIR absorbing nanoparticles may be organized in one single plan or discrete plans so as to form at least one NIR absorbing nanoparticle layer within the inorganic matrix.

The diameter of the NIR absorbing nanoparticles may be from 0.2 to 150 nm, such as 0.5 to 100 nm, or even 1 to 50 nm. The diameter of the NIR absorbing nanoparticles may be measured with a transmission electron microscope.

In an embodiment, the NIR absorbing coating is made of an inorganic matrix containing NIR absorbing nanoparticles. In an embodiment, the inorganic matrix may be based on oxide, nitride or oxynitride materials, such as silicon oxide, silicon nitride, silicon oxynitride, silicon zirconium nitride, titanium oxide, aluminum oxide, zinc oxide, niobium oxide, bismuth oxide, lead oxide, aluminum-doped zinc oxide, gallium-doped zinc oxide, tin zinc oxide, magnesium zinc oxide, magnesium oxide or molybdenum oxide or combination thereof. In a particular embodiment, the inorganic matrix is based on silicon oxide, silicon nitride, silicon oxynitride, titanium oxide, zinc oxide or niobium oxide.

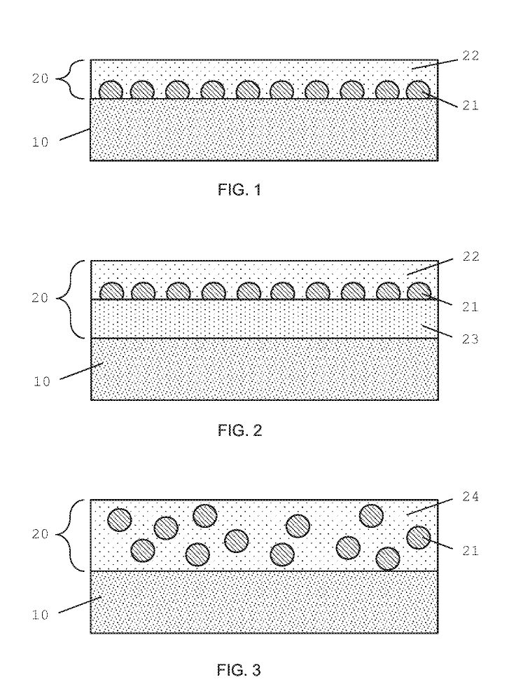

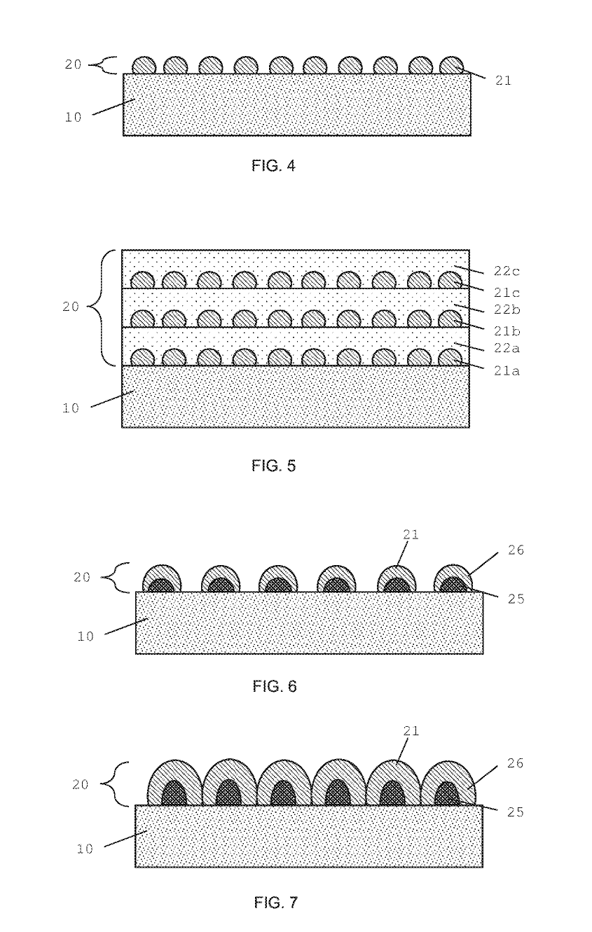

In the present application, by “an inorganic matrix containing NIR absorbing nanoparticles” it is meant that the nanoparticles are confined within the inorganic matrix or at least covered by the inorganic matrix. The inorganic matrix may be formed by one single layer or several layers made of the same or different materials. In particular, the NIR absorbing nanoparticles may be sandwiched between two layers forming the inorganic matrix. Accordingly, the NIR absorbing coating may comprise at least one of the following NIR absorbing structures:
[1] a NIR absorbing nanoparticle layer and an inorganic overlayer directly on said NIR absorbing nanoparticle layer, as illustrated for example in FIG. 1;
[2] an inorganic underlayer, a NIR absorbing nanoparticle layer directly on said inorganic underlayer, and an overlayer directly on said NIR absorbing nanoparticle layer, as illustrated for example in FIG. 2;
[3] NIR absorbing nanoparticles dispersed within an inorganic encapsulating layer, as illustrated for example in FIG. 3; and
[4] a NIR absorbing nanoparticle layer, as illustrated for example in FIG. 4.

The overlayers, the underlayers and the encapsulating layer of structures [1], [2] and [3] may be based on oxide, nitride or oxynitride materials, as described above for the inorganic matrix.

The quantity of NIR absorbing nanoparticles in structures [1], [2], [3] and [4] may be expressed by their surface density. In order to be independent from the degree of oxidation of the material, the surface density of the NIR absorbing nanoparticles is expressed by the surface density of the metallic atoms involved in the NIR absorbing nanoparticles. The surface density of the NIR absorbing nanoparticles can be determined by microanalysis using an electron microprobe (EMP), optionally coupled with secondary ion mass spectrometry (SIMS). An “equivalent theoretical layer thickness” corresponding to the thickness of a theoretical continuous layer made of an equivalent surface density can then be deduced by dividing the measured surface density with the density of the material of the NIR absorbing nanoparticles. The use of the equivalent theoretical layer thickness in place of the surface density may be particularly adapted for characterizing structures [1], [2] and [4] wherein the NIR absorbing nanoparticles form a layer. The equivalent theoretical layer thickness can also be determined from the process parameters as will be explained thereafter. The equivalent theoretical layer thickness corresponding to the quantity of NIR absorbing nanoparticles may be from 0.5 to 70 nm, such as from 1 to 50 nm or even 2 to 20 nm.

Referring to FIGS. 1 to 4, the functionalized substrate comprises a substrate 10 and a NIR absorbing coating 20 on said substrate 10. On FIG. 1, the NIR absorbing coating 20 is made of one structure [1] comprising NIR absorbing nanoparticles 21 forming a layer and an overlayer 22 directly on the NIR absorbing nanoparticles layer. The NIR absorbing nanoparticles layer may have an equivalent theoretical layer thickness up to 150 nm, such as up to 100 nm or even up to 50 nm, for example from 0.5 to 20 nm or even from 1 to 15 nm. The overlayer may have a thickness of 1 to 200 nm, for example from 2 to 100 nm, even from 10 to 50 nm. Structure [1] may have a physical thickness from 1 to 200 nm, for example from 2 to 100 nm, even from 10 to 50 nm. FIG. 2 shows a NIR absorbing coating 20 made of one structure [2] comprising an under layer 23, NIR absorbing nanoparticles 21 forming a layer directly on the under layer 23 and an overlayer 22 directly on the NIR absorbing nanoparticles layer. In structure [2], the underlayer 23 and the overlayer 22 may be based on the same or different materials. The NIR absorbing nanoparticle layer may have an equivalent theoretical layer thickness up to 150 nm, such as up to 100 nm or even up to 50 nm, for example from 0.5 to 20 nm or even from 1 to 15 nm. The overlayer may have a thickness of 1 to 200 nm, for example from 2 to 100 nm, even from 10 to 50 nm. The underlayer may have a thickness of 1 to 200 nm, for example from 2 to 100 nm, even from 10 to 50 nm. Structure [2] may have a physical thickness from 2 to 500 nm, for example from 5 to 200 nm, even from 10 to 100 nm or from 15 to 50 nm. On FIG. 3, the NIR absorbing coating 20 is made of one structure [3] comprising NIR absorbing nanoparticles 21 dispersed within an encapsulating layer 24. The encapsulating layer, as well as structure [3], may have a thickness from 2 to 200 nm, for example from 5 to 100 nm, even from 10 to 50 nm. FIG. 4 shows a NIR absorbing coating 20 made of one structure [4] comprising NIR absorbing nanoparticles 21 forming a layer. The NIR absorbing nanoparticle layer may have an equivalent theoretical layer thickness up to 150 nm, such as up to 100 nm or even up to 50 nm, for example from 0.5 to 20 nm or even from 1 to 15 nm. In certain embodiments, illustrated, for example in FIGS. 6 and 7, the oxidation of the metallic clusters may be performed until NIR absorbing nanoparticles 21 having a core shell structure with a metallic core 25 and a TCO shell 26 are obtained. These core shell structures may be particularly suitable for use in structure [4]. In an embodiment, the NIR absorbing nanoparticles 21 may be spaced apart from one another (FIG. 6). In another embodiment, the NIR absorbing nanoparticles 21 may contact one another (FIG. 7).

In certain embodiments, the NIR absorbing coating may comprise a plurality of structures, such as at least 2, at least 3, or at least 4 structures and up to 5, up to 7 and even up to 10 structures, each being independently selected from structures [1], [2], [3] and [4]. The plurality of structures may comprise all combinations of structures [1], [2], [3] and [4], such as combinations of at least one structure [1], at least one structure [2], at least one structure [3] and at least one structure [4], combinations of at least one structure [1] and at least one structure [2], combinations of at least one structure [1] and at least one structure [3], combinations of at least one structure [1] and at least one structure [4], combinations of at least one structure [2] and at least one structure [3], combinations of at least one structure [2] and at least one structure [4], combinations of at least one structure [3] and at least one structure [4], or combinations of only structures of the same type. In an embodiment, the plurality of structures may include only one structure [4], optionally in combination with at least one of structure [1], structure [2] and structure [3], where structure [4] is the uppermost of the NIR absorbing coating. In one particular embodiment, the NIR absorbing coating may comprise a plurality of structures [1]. Accordingly, the NIR absorbing coating may comprise a first NIR absorbing nanoparticles layer, a first inorganic overlayer directly on said first NIR absorbing nanoparticles layer, a second NIR absorbing nanoparticles layer directly on said first inorganic overlayer, and a second inorganic overlayer directly on said second NIR absorbing nanoparticle layer. The first and second NIR absorbing nanoparticle layers, respectively the first and second overlayers, may be based on the same or different materials. For example, FIG. 5 shows a functionalized substrate comprising a NIR absorbing coating 20 made of 3 structures [1] and thus comprising NIR absorbing nanoparticles 21a forming a first NIR absorbing nanoparticles layer on the substrate 10, a first overlayer 22a directly on the first NIR absorbing nanoparticles layer, NIR absorbing nanoparticles 21b forming a second NIR absorbing nanoparticles layer directly on the first overlayer 22a, a second overlayer 22b directly on the second NIR absorbing nanoparticles layer, NIR absorbing nanoparticles 21c forming a third NIR absorbing nanoparticles layer directly on the second overlayer 22b and a third overlayer 22c directly on the third NIR absorbing nanoparticles layer. In another particular embodiment, the NIR absorbing coating may comprise a plurality of structures [2]. In still another particular embodiment, the NIR absorbing coating may comprise a plurality of structures [3]. When the NIR absorbing coating comprises several structures of the same type, said structures may be based on the same or different materials. In a simple embodiment, all the structures of the same type may be based on the same materials. In other embodiments, the structures of the same type may be based on different materials. For example, the inorganic material forming the underlayer, the overlayer or the encapsulating layer may be similar while the materials forming the NIR absorbing nanoparticles may be different from one other, or vice versa.

The physical thickness of the NIR absorbing coating depends of course on the number of structures [1], [2], [3] and [4] involved in this coating. For example, the NIR absorbing coating may have a physical thickness from 2, 5 or 10 nm to up to 0.5 or 1 μm or even several microns, such as 2 or 5 μm.

The substrate can be organic or inorganic. The substrate may include glass, glass-ceramic, or organic polymeric material. In an embodiment, the substrate may be transparent, i.e. having a visible light transmission (VLT) measured according to the standard ISO 9050:2003 of more than 80%, preferably more than 90%, more preferably more than 95%, or colored, for example blue, grey, green or bronze. The glass may be a boro-silicate or alumino-silicate glass. The organic polymeric material may be polycarbonate (PC), polymethylmethacrylate (PMMA), polyethylene terephtalate (PET), polyethylene naphtalate (PEN), polyurethane (PU), polyvinyl butyral (PVB), ethylene-vinyl acetate (EVA), fluorinated polymers such as ethylene tetrafluoroethylene (ETFE), or cellulose resin. Depending of its nature, the substrate may have a thickness from 5 μm to 20 mm. A glass or glass-ceramic substrate may have a thickness from 0.5 to 20 mm, such as from 4 to 6 mm. In an embodiment, the substrate may include, consist of, or consist essentially of a flexible polymer substrate made for example of PET, PEN, PU, PVB, EVA, ETFE or cellulose resin, and having a thickness from 5 to 200 μm, such as from 10 to 100 μm.

In certain embodiments, a process for producing a functionalized substrate can include:
providing a substrate; and
depositing NIR absorbing nanoparticles on said substrate.

In further embodiments, the process for producing the functionalized substrate can include:
depositing an inorganic matrix on said substrate.

More specifically, the present invention relates to a process for producing a functionalized substrate comprising:
providing a substrate; and
depositing at least one structure selected from structure [1], structure [2], structure [3], and structure [4] on said substrate;
   wherein:
   depositing structure [1] comprises:
depositing an NIR absorbing nanoparticles layer on said substrate; and
depositing an inorganic overlayer directly on said NIR absorbing nanoparticles layer;
   depositing structure [2] comprises:
depositing an inorganic underlayer on said substrate;
depositing an NIR absorbing nanoparticles layer directly on said inorganic underlayer; and
depositing an inorganic overlayer directly on said NIR absorbing nanoparticles layer;
   depositing structure [3] comprises:
depositing simultaneously NIR absorbing nanoparticles and an inorganic encapsulating layer on said substrate;
   and depositing structure [4] comprises:
depositing an NIR absorbing nanoparticles layer on said substrate.

The substrate, the NIR absorbing nanoparticles, the inorganic matrix, the inorganic overlayer, the inorganic underlayer and the inorganic encapsulating layer may be as described above for the functionalized substrate.

In an embodiment, the NIR absorbing nanoparticles and the inorganic matrix are deposited by magnetron sputtering or reactive magnetron sputtering. Magnetron sputtering is a deposition method commonly used for depositing thin layers on a substrate. Magnetron sputtering refers to magnetic field assisted cathode sputtering. In reactive magnetron sputtering, the deposited material is formed by chemical reaction between the target material (i.e. the cathode) and a gas, generally oxygen, nitrogen or mixture thereof. When very thin layers of materials are deposited a de-wetting phenomenon of the solid thin layer can occur. This phenomenon is common for silver and gold thin layers. Very thin layers may thus not be continuous layers. In particular, sputtering low material quantity may result in the deposition of discrete clusters instead of continuous layer. In accordance with certain embodiments, the “percolation threshold” is defined as the limit of the sputtered material quantity under which discrete clusters can be obtained. The sputtered material quantity may be deduced from the process parameters. Although a continuous layer may not be obtained, an “equivalent theoretical layer thickness” corresponding to the thickness of a theoretical continuous layer obtained with a given sputtered material quantity can be defined. The equivalent theoretical layer thickness depends on the power applied to the target and on the speed of motion of the substrate. Of course, when the layer is a continuous layer, the equivalent theoretical layer thickness is equal to the real thickness of the layer. The equivalent theoretical layer thickness can thus be determined by considering the speed of motion of the substrate during the deposition of the NIR nanoparticles and the quantity of material sputtered per unit of time. For example, if for given sputtering conditions a continuous layer having a thickness of 10 nm is obtained, the equivalent theoretical layer thickness of a discontinuous layer or discrete clusters obtained when the speed of motion of the substrate is increased by a factor of 2, all other parameters being equal, would be 5 nm.

The percolation threshold depends on the material to be sputtered. The percolation threshold can be determined for a given material by tests. For example, the percolation threshold for an InSn alloy with a weight ratio ranging from 95:5 to 80:20 corresponds to an equivalent theoretical layer thickness of more than 150 nm. For a SnSb alloy with a weight ratio ranging from 95:5 to 60:40 the percolation threshold corresponds to an equivalent theoretical layer thickness of around 8 nm.

The NIR absorbing nanoparticles which are based on at least partially oxidized metals or alloys may be obtained either by magnetron sputtering using targets having a composition corresponding to the desired nanoparticles; by reactive magnetron sputtering under oxygen using targets having lower oxygen content than the desired nanoparticles, typically metallic targets; or by depositing metallic clusters by magnetron sputtering using metallic targets and oxidizing the metallic clusters.

In one embodiment, the NIR absorbing nanoparticles may be obtained directly by magnetron sputtering. In other words, the desired degree of oxidation for the NIR absorbing nanoparticles may be reached, in one step, directly during the magnetron sputtering. For example, TCO nanoparticles may be obtained directly by using targets having corresponding compositions, optionally using reactive magnetron sputtering under oxygen. This embodiment is particularly adapted to the deposition of structure [3]. More specifically, structure [3] may be deposited by co-sputtering using a combination of metallic and/or oxide targets, one target providing the material for the NIR absorbing nanoparticles and another target providing the material for the encapsulating layer, so that the NIR absorbing nanoparticles and the encapsulating layer are deposited simultaneously. For example, a combination of a metallic target for depositing the NIR absorbing nanoparticles and an oxide target for depositing the encapsulating layer may be used. The materials for the NIR absorbing nanoparticles and for the encapsulating layer may be immiscible so as to obtain a phase segregation of the NIR absorbing nanoparticles within the encapsulating layer. In another embodiment, the deposition of the NIR absorbing nanoparticles can include:
depositing metallic clusters; and
oxidizing said metallic clusters so as to obtain NIR absorbing nanoparticles.

Here, the expression “metallic clusters” may also include partially oxidized metallic clusters.

This embodiment is particularly adapted to the deposition of structures [1], [2] and [4]. When the inorganic overlayer is based on an oxide material, such as silicon oxide, the oxidation of the metallic clusters may occur during the deposition of the inorganic overlayer with the presence of oxygen in the reactive plasma. When the inorganic layer is not based on an oxide material, or when the desired degree of oxidation for the NIR absorbing nanoparticles cannot be reached through the oxidation provided by the deposition of the inorganic overlayer, the metallic clusters may be subjected to an additional oxidation step. Accordingly, the deposition of structure [1] may include:
depositing a metallic cluster layer on the substrate;
optionally, oxidizing the metallic cluster layer; and
depositing an inorganic overlayer directly on said metallic clusters layer or oxidized metallic clusters layer.

Similarly, the deposition of structure [2] may include:
depositing an inorganic underlayer on the substrate;
depositing a metallic clusters layer directly on said underlayer;
optionally, oxidizing the metallic clusters layer; and
depositing an inorganic overlayer directly on said metallic clusters layer or oxidized metallic clusters layer.

The deposition of structure [4] may include:
depositing a metallic cluster layer on the substrate; and
oxidizing the metallic cluster layer.

The oxidation of the metallic clusters may be performed before the deposition of the inorganic overlayer. In certain embodiments, the oxidation of the metallic clusters may be performed by simply contacting the metallic clusters layer with an oxygen-containing gas introduced in the deposition chamber before the deposition of the inorganic overlayer. In other embodiments, the oxidation of the metallic clusters may be performed by submitting the metallic clusters layer to a heat treatment under oxygen-containing gas before the deposition of the inorganic overlayer. The oxygen-containing gas may be oxygen, a mixture of oxygen and nitrogen, or a mixture of oxygen and an inert gas such as argon. Such mixture may allow a better control of the oxidation of the metallic clusters. In still other embodiments, the oxidation of the metallic clusters may be performed by submitting the metallic clusters layer to oxidative plasma before the deposition of the inorganic overlayer. Of course any combinations of the above embodiments for oxidizing the metallic clusters may be used. For example, the oxidation of the metallic clusters may be performed by both submitting the metallic clusters layer to a heat treatment under oxygen-containing gas and to oxidative plasma before the deposition of the inorganic overlayer. In certain embodiments, the oxidation of the metallic clusters may be performed until NIR absorbing nanoparticles based on TCO are obtained. In certain other embodiments, as discussed previously and as illustrated, for example in FIGS. 6 and 7, the oxidation of the metallic clusters may be performed until NIR absorbing nanoparticles 21 having a core shell structure with a metallic core 25 and a TCO shell 26 are obtained.

The process for producing a functionalized substrate may further include an annealing step. The annealing step may increase the degree of oxidation of the NIR absorbing nanoparticles. The annealing temperature may be from 50 to 800° C., such as 80 to 500° C., even 100 to 400° C. When the substrate is made of polymeric material, the annealing step may be performed at low temperatures, such as no more than 300° C., no more than 200° C., no more than 150° C., or even no more than 120° C. When the substrate is made of inorganic material such as glass or glass-ceramic, the annealing step may be performed at higher temperature such as more than 200° C., more than 500° C., or even more than 600° C. The duration of the annealing step depends on the temperature. Indeed, depending on the materials of the NIR absorbing nanoparticles, the NIR absorbing properties of the nanoparticles may be affected by excessive oxidation. The duration of the annealing step will depend on the temperature. Generally, the higher the temperature, the shorter the annealing step. For example, for temperatures from 100 to 400° C., the duration of the annealing step may be from 5 minutes to 4 hours, such as from 10 minutes to 3 hours, or even from 0.5 to 2 hours. The annealing step may be performed after the deposition of the inorganic matrix.

In another aspect, the present invention relates to a window film including the functionalized substrate described above. In this case, the substrate is a flexible polymer substrate made for example of PET, PEN, PU, PVB, EVA, ETFE or cellulose resin. The flexible polymer substrate may be provided with a hard coat. The hard coat can be provided on the lower surface of the substrate, i.e. the surface opposite to the NIR absorbing coating. The hard coat may be based on silica nanoparticles dispersed in a resin such as an acrylate resin.

The window film may include other functional layers, for example optical layers or IR reflecting layers, such as silver layers. In certain embodiments, the window film can be free of any silver layer, or even free of any metal layer.

A counter flexible polymer substrate may be provided on the functionalized substrate, i.e. on the layer furthest to the flexible polymer substrate, such as through an adhesive layer. The counter flexible polymer substrate may be made of a similar or different material than the flexible polymer substrate, for example PET, PEN, PU, PVB, EVA, ETFE or cellulose resin.

In certain embodiments, a method for improving the solar control of a glazing, such as building glazings or vehicle glazings, can include the steps of providing the window film as described herein; and depositing the infrared reflecting film on the surface of the glazing. The window film may be deposited on the glazing with the flexible polymer substrate furthest to the glazing.

In certain embodiments, a method for manufacturing a glazing can include the step of providing the window film on the surface of the glazing. The film of the present invention may be laminated on the glazing and adhered to the glazing through an adhesive layer, such as a PSA layer. The window film may be laminated on the surface of the glazing with the flexible polymer substrate furthest to the glazing.

Embodiment of the functionalized substrate of the present invention will now be illustrated with the following non-limiting example.

### EXAMPLE

A functionalized substrate having a NIR absorbing coating formed of a SiO₂ matrix containing ITO-based nanoparticles has been prepared. An InSn metallic cluster layer, corresponding to an equivalent theoretical layer thickness of 10 nm, has first been deposited by magnetron sputtering on a PET substrate. Then the substrate with the InSn metallic clusters thereon has been submitted to an oxidative plasma (1500 standard cubic centimeters per minute (sccm) O₂ and 50 sccm Ar) with a speed of 0.25 m/min. A 40 nm thick SiO₂ layer has then been deposited by magnetron sputtering on the oxidized InSn clusters. Finally, the coated substrate has been annealed under ambient air at 300° C. for 1 hour 30 minutes.

Table 1 shows the operating conditions for the magnetron sputtering deposition for each type of layer.

TABLE 1

| | | Operating | |
|---|---|---|---|
| Layer | Target | pressure | Gas |
| InSn clusters | InSn (90:10 wt %) | 4 μBar | Ar (20 sccm) |
| SiO₂ | Si:Al | 3 μBar | Ar:O₂ (20:10 sccm) |

The energy absorption, also called solar direct absorbance, of the functionalized substrate thus obtained, measured according to ISO 9050:2003, reached 30%.

Many different aspects and embodiments are possible. Some of those aspects and embodiments are described below. After reading this specification, skilled artisans will appreciate that those aspects and embodiments are only illustrative and do not limit the scope of the present invention. Exemplary embodiments may be in accordance with any one or more of the embodiments as listed below.

### Embodiment 1

A functionalized substrate comprising a substrate (10) and a near infrared absorbing coating (20), wherein said near infrared absorbing coating (20) comprises near infrared absorbing nanoparticles (21) comprising indium, tin, zinc, antimony, aluminum, tungsten or mixtures thereof.

### Embodiment 2

The functionalized substrate according to embodiment 1, wherein the near infrared absorbing nanoparticles (21) comprise transparent conductive oxide.

### Embodiment 3

The functionalized substrate according to any one of embodiments 1 or 2, wherein the near infrared absorbing nanoparticles (21) have a core-shell structure with a metallic core and an at least partially oxidized shell.

### Embodiment 4

The functionalized substrate according to any one of embodiments 1 to 3, wherein the transparent conductive oxide is selected from indium tin oxide, indium zinc oxide, antimony tin oxide, tin zinc oxide, fluorine-doped tin oxide, aluminum-doped zinc oxide, gallium-doped zinc oxide, or optionally doped tungsten oxide.

### Embodiment 5

The functionalized substrate according to any one of embodiments 1 to 4, wherein the near infrared absorbing nanoparticles (21) have a diameter from 0.2 to 150 nm.

### Embodiment 6

The functionalized substrate according to any one of embodiments 1 to 5, wherein the near infrared absorbing nanoparticles (21) are spaced apart from each other.

### Embodiment 7

The functionalized substrate according to any one of embodiments 1 to 6, wherein the near infrared absorbing coating (20) comprises at least one of the following NIR absorbing structures: a near infrared absorbing nanoparticles (21) layer and an inorganic overlayer (22) directly on said near infrared absorbing nanoparticles (21) layer; an inorganic underlayer (23), a near infrared absorbing nanoparticles (21) layer directly on said inorganic underlayer (23), and an overlayer (22) directly on said near infrared absorbing nanoparticles (21) layer; near infrared absorbing nanoparticles (21) dispersed within an inorganic encapsulating layer (24); and a near infrared absorbing nanoparticles (21) layer where the near infrared absorbing nanoparticles (21) have a core-shell structure.

### Embodiment 8

The functionalized substrate according to any one of embodiments 1 to 7, wherein said near infrared absorbing coating (20) further comprises an inorganic matrix (22, 23, 24) based on oxide, nitride or oxynitride materials.

### Embodiment 9

A process for manufacturing a functionalized substrate comprising: providing a substrate (10); and depositing near infrared absorbing nanoparticles (21) by magnetron sputtering on said substrate (10).

### Embodiment 10

The process according to embodiment 9, wherein depositing near infrared absorbing nanoparticles further comprises: depositing at least one structure selected from structure [1], structure [2], structure [3] and structure [4] on said substrate (10); wherein: depositing structure [1] comprises: depositing an near infrared absorbing nanoparticles (21) layer on said substrate (10); and depositing an inorganic overlayer (22) directly on said near infrared absorbing nanoparticles (21) layer; depositing structure [2] comprises: depositing an inorganic underlayer (23) on said substrate (10); depositing an near infrared absorbing nanoparticles (21) layer directly on said inorganic underlayer (23); and depositing an inorganic overlayer (22) directly on said near infrared absorbing nanoparticles (21) layer; depositing structure [3] comprises: depositing simultaneously near infrared absorbing nanoparticles (21) and an inorganic encapsulating layer (24) on said substrate (10); and depositing structure [4] comprises: depositing an near infrared absorbing nanoparticles (21) layer on said substrate (10).

### Embodiment 11

The process according to embodiment 9 or 10, wherein the deposition of the near infrared absorbing nanoparticles (21) comprises: depositing metallic clusters; and oxidizing said metallic clusters so as to obtain near infrared absorbing nanoparticles (21).

### Embodiment 12

The method according to embodiment 11, wherein said metallic clusters are based on indium, tin, zinc, antimony, aluminum, tungsten or alloys thereof.

### Embodiment 13

The method according to any one of embodiments 9 to 12, wherein said method further comprises an annealing step.

### Embodiment 14

A window film comprising the functionalized substrate according to any one of embodiments 1 to 8, wherein the substrate is a flexible polymer substrate.

### Embodiment 15

A glazing comprising the window film according to embodiment 14.

Note that not all of the activities described above in the general description or the examples are required, that a portion of a specific activity may not be required, and that one or more further activities may be performed in addition to those described. Still further, the order in which activities are listed is not necessarily the order in which they are performed.

Certain features that are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

1. A functionalized substrate comprising a substrate and a near infrared absorbing coating, wherein said near infrared absorbing coating comprises near infrared absorbing nanoparticles comprising indium, tin, zinc, antimony, aluminum, tungsten or mixtures thereof.

2. The functionalized substrate according to claim 1, wherein the near infrared absorbing nanoparticles comprise a transparent conductive oxide selected from the group consisting of indium tin oxide, indium zinc oxide, antimony tin oxide, tin zinc oxide, fluorine-doped tin oxide, aluminum-doped zinc oxide, gallium-doped zinc oxide, and optionally doped tungsten oxide.

3. The functionalized substrate according to claim 1, wherein the near infrared absorbing nanoparticles have a core-shell structure with a metallic core and an at least partially oxidized shell.

4. The functionalized substrate according to claim 2, wherein the transparent conductive oxide is indium tin oxide.

5. The functionalized substrate according to claim 1, wherein the near infrared absorbing nanoparticles have a diameter from 0.2 to 150 nm.

6. The functionalized substrate according to claim 1, wherein the near infrared absorbing nanoparticles are spaced apart from each other.

7. The functionalized substrate according to claim 1, wherein the near infrared absorbing coating comprises near infrared absorbing nanoparticles dispersed within an inorganic encapsulating layer.

8. The functionalized substrate according to claim 1, wherein the near infrared absorbing coating comprises an inorganic underlayer, a near infrared absorbing nanoparticles layer directly on said inorganic underlayer, and an overlayer directly on said near infrared absorbing nanoparticles layer.

9. The functionalized substrate according to claim 1, wherein the near infrared absorbing nanoparticles have an equivalent theoretical layer thickness from 0.5 nm to 70 nm.

10. The functionalized substrate according to claim 1, wherein said near infrared absorbing coating further comprises an inorganic matrix based on oxide materials, nitride materials, or oxynitride materials.

11. The functionalized substrate according to claim 1, wherein the near infrared absorbing coating comprises a first near infrared absorbing nanoparticles layer, a first inorganic overlayer directly on said first near infrared absorbing nanoparticles layer, a second near infrared absorbing nanoparticles layer directly on said first inorganic overlayer, and a second inorganic overlayer directly on said second near infrared absorbing nanoparticles layer

12. The functionalized substrate according to claim 1, wherein the substrate comprises a glass.

13. A window film comprising the functionalized substrate according to claim 1, wherein the substrate is a flexible polymer substrate.

14. A glazing comprising the window film according to claim 13.

15. A process for manufacturing a functionalized substrate comprising:
providing a substrate; and
depositing near infrared absorbing nanoparticles by magnetron sputtering on said substrate.

16. The process according to claim 15, wherein depositing near infrared absorbing nanoparticles comprises:
depositing an inorganic underlayer on said substrate;
depositing an near infrared absorbing nanoparticles layer directly on said inorganic underlayer; and
depositing an inorganic overlayer directly on said near infrared absorbing nanoparticles layer.

17. The process according to claim 15, wherein depositing near infrared absorbing nanoparticles comprises depositing simultaneously near infrared absorbing nanoparticles and an inorganic encapsulating layer on said substrate.

18. The process according to claim 15, wherein depositing near infrared absorbing nanoparticles comprises:
depositing metallic clusters; and
oxidizing said metallic clusters so as to obtain near infrared absorbing nanoparticles.

19. The process according to claim 18, wherein said metallic clusters are based on indium, tin, zinc, antimony, aluminum, tungsten or alloys thereof.

20. The process according to claim 19, wherein said process comprises an annealing step.
